(19) United States
(12) Patent Application Publication
(10) Pub. No.: US 2026/0090129 A1
(43) Pub. Date: Mar. 26, 2026

(54) LIGHT SENSOR INTEGRATED CIRCUIT AND MANUFACTURING METHOD THEREOF

(71) Applicant: PIXART IMAGING INC., Hsin-Chu County (TW)

(72) Inventors: Kheng Chong TEOH, Penang (MY); Yoon Seng ONE, Penang (MY)

(21) Appl. No.: 18/896,905

(22) Filed: Sep. 26, 2024

(51) Int. Cl. H01L 31/16; H01L 31/02; H01L 31/0224; H01L 31/18

(52) U.S. Cl. CPC H10F 55/26; H10F 71/00; H10F 77/206; H10F 77/933

(57) ABSTRACT

There is provided a light sensor integrated circuit including a silicon bond pad, a light source die and a photodiode. The silicon bond pad is formed with conductive epoxy using non-contact dispensing. The conductive epoxy is used to fix the light source die on the silicon bond pad. The light source die is used to emit light toward an encoding medium to generate modulated reflection light propagating to the photodiode.

### FIELD OF THE DISCLOSURE

This disclosure generally relates to a light sensor integrated circuit (IC) and, more particularly, to a light sensor IC having a silicon bond pad on a surface thereof used as a substrate for attaching a light source die, and a manufacturing method of the light sensor IC.

### BACKGROUND OF THE DISCLOSURE

The light sensor generally includes a light emitting diode (LED) die and a light sensor integrated circuit (IC) respectively arranged on a leadframe or a printed circuit board (PCB). Conventionally, a stamping tool is firstly used to transfer conductive epoxy to a surface of the leadframe or the PCB, and then the LED die and the light sensor IC are attached to the leadframe or the PCB.

However, the stamping tool directly presses on a stamped surface to transfer the conductive epoxy, and the stamped surface can be damaged when the stamped surface is made of fragile material. In addition, a fillet thickness of the conductive epoxy being transferred is lower by using the stamping process such that the LED die may not be fully covered by the conductive epoxy to have low shear strength.

The information disclosed in this BACKGROUND is merely intended to increase understanding of the general background of the invention and should not be taken as an admission or in any way implied that the relevant information constitutes prior art that is already known to a person of ordinary skill in the art.

### SUMMARY

Accordingly, the present disclosure provides a light sensor IC with a light source die being directly attached on a silicon bond pad thereof so as to reduce a total package size, and a manufacturing method of the light sensor IC.

The present disclosure provides a manufacturing method of a light sensor IC that uses non-contact dispensing for attaching a light source die onto a silicon bond pad of the light sensor IC in order not to damage the silicon bond pad.

The present disclosure provides a light sensor IC including a silicon bond pad, a light source die and conductive epoxy. The silicon bond pad is on a surface of the light sensor IC. The conductive epoxy is configured to fix the light source die on the silicon bond pad and electrically connect thereto.

The present disclosure further provides a manufacturing method of a light sensor IC. The light sensor IC includes a silicon bond pad on a surface thereof. The manufacturing method includes: dispensing a conductive epoxy region on the silicon bond pad using non-contact dispensing; attaching a light source die to the conductive epoxy region; forming a first bonding wire to connect a first bond pad on the surface of the light sensor IC with the light source die; and forming a second bonding wire to connect a second bond pad on the surface of the light sensor IC with the silicon bond pad.

The present disclosure further provides a manufacturing method of a light sensor IC. The light sensor IC includes a silicon bond pad on a surface thereof. The manufacturing method includes: forming a second bonding wire to connect a second bond pad on the surface of the light sensor IC with the silicon bond pad; dispensing a conductive epoxy region on the silicon bond pad using non-contact dispensing to cover a bond between the second bonding wire and the silicon bond pad; attaching a light source die to the conductive epoxy region; and forming a first bonding wire to connect a first bond pad on the surface of the light sensor IC with the light source die.

### BRIEF DESCRIPTION OF DRAWINGS

Other objects, advantages, and novel features of the present disclosure will become more apparent from the following detailed description when taken in conjunction with the accompanying drawings.

FIG. 1 is a top view of a light sensor IC according to one embodiment of the present disclosure.

FIG. 2A is a schematic diagram of disposing stud bumps on a surface of silicon bond pad in a manufacturing method of a light sensor IC according to a first embodiment of the present disclosure.

FIG. 2B is a schematic diagram of dispensing conductive epoxy on a surface of silicon bond pad in a manufacturing method of a light sensor IC according to a first embodiment of the present disclosure.

FIG. 2C is a schematic diagram of attaching a light source die to the conductive epoxy on a surface of silicon bond pad in a manufacturing method of a light sensor IC according to a first embodiment of the present disclosure.

FIG. 2D is a schematic diagram of forming bonding wires connected to the silicon bond pad in a manufacturing method of a light sensor IC according to a first embodiment of the present disclosure.

FIG. 3A is a schematic diagram of disposing stud bumps and a bonding wire on a surface of silicon bond pad in a manufacturing method of a light sensor IC according to a second embodiment of the present disclosure.

FIG. 3B is a schematic diagram of dispensing conductive epoxy on a surface of silicon bond pad in a manufacturing method of a light sensor IC according to a second embodiment of the present disclosure.

FIG. 3C is a schematic diagram of attaching a light source die to the conductive epoxy on a surface of silicon bond pad in a manufacturing method of a light sensor IC according to a second embodiment of the present disclosure.

FIG. 3D is a schematic diagram of forming another bonding wire in a manufacturing method of a light sensor IC according to a second embodiment of the present disclosure.

### DETAILED DESCRIPTION OF THE DISCLOSURE

It should be noted that, wherever possible, the same reference numbers will be used throughout the drawings to refer to the same or like parts.

One objective of the present disclosure is to provide a light sensor integrated circuit (IC) on which a light source die is attached to a silicon bond pad of the light sensor IC using non-contact dispensing to reduce a package size, to avoid damaging the silicon bond pad during manufacturing and to improve the shear strength, and a manufacturing method of the light sensor IC.

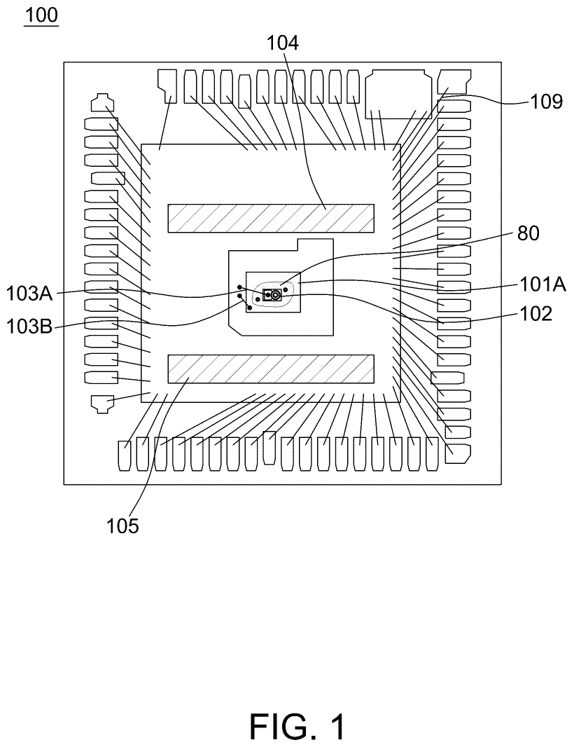

Please refer to FIG. 1, it is a top view of a light sensor IC 100 according to one embodiment of the present disclosure. The light sensor IC 100 of the present disclosure is adapted to, for example, an absolute optical encoder. The absolute optical encoder includes an encoding medium formed with AB slits and index slits thereon, and arranged opposite to the light sensor IC 100. An example of forming the AB slits and the index slits on an encoding medium may be referred to U.S. Patent Application No. U.S. Ser. No. 16/583,972, entitled “OPTICAL ENCODER WITH COVERED PHOTO DIODE” filed on Sep. 26, 2019, assigned to the same assignee of the present application, and the full disclosure of which is incorporated herein by reference.

Please refer to FIG. 1, a surface of the light sensor IC 100 includes a pad area (e.g., having multiple pads at peripheries thereof) and a circuitry area (e.g., having multiple components at a center thereof) connected to each other via multiple bonding wires 109. The surface of the light sensor IC 100 further includes a silicon bond pad 101A, a light source die 102, a first bonding wire 103A, a second bonding wire 103B, a first photodiode 104, a second photodiode 105 and conductive epoxy 80, which is, for example, a silver epoxy, but not limited thereto.

The silicon bond pad 101A is arranged between the first photodiode 104 and the second photodiode 105 on the surface of the light sensor IC 100. In one aspect, the first photodiode 104 is, for example, an incremental photodiode for receiving modulated light reflected from the AB slits of an encoding medium. In one aspect, the second photodiode 105 is, for example, an absolute photodiode for receiving modulated light reflected from the index slits of the encoding medium. In FIG. 1, the first photodiode 104 and the second photodiode 105 are shown as rectangular regions with a length direction extending along left and right directions, e.g., each of 104 and 105 including multiple photodiodes arranged adjacent to each other in the left and right directions. The silicon bond pad 101A is disposed between the first photodiode 104 and the second photodiode 105 along up and down directions on the surface of the light sensor IC 100.

The light source die 102 is, for example, a light emitting diode (LED) die or a laser diode die, and is used to emit recognizable light to illuminate an encoding medium (e.g., encoding disk, not shown herein). The light source die 102 is disposed on and attached to a surface of the silicon bond pad 101A using a pick and place device. The operation of the pick and place device is known to the art and not a main objective of the present disclosure, and thus details thereof are not described herein.

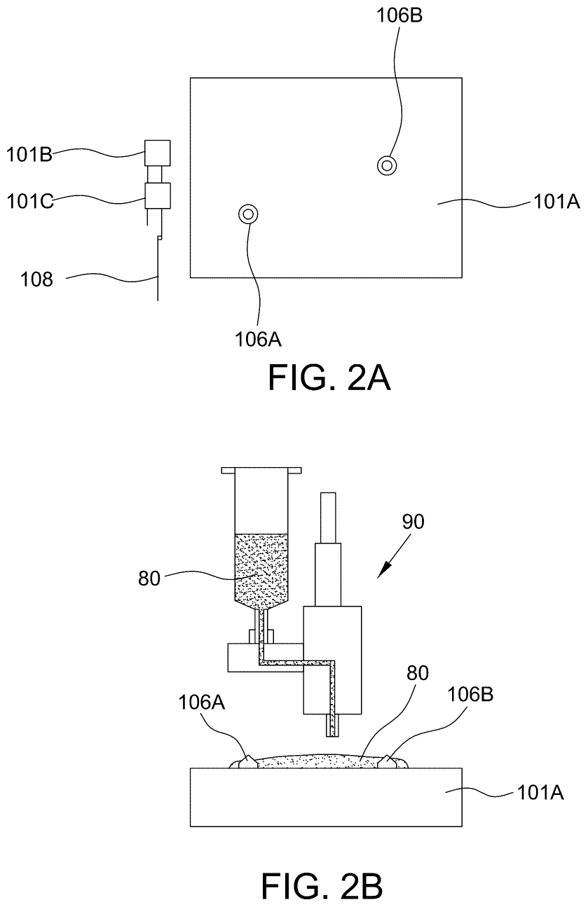

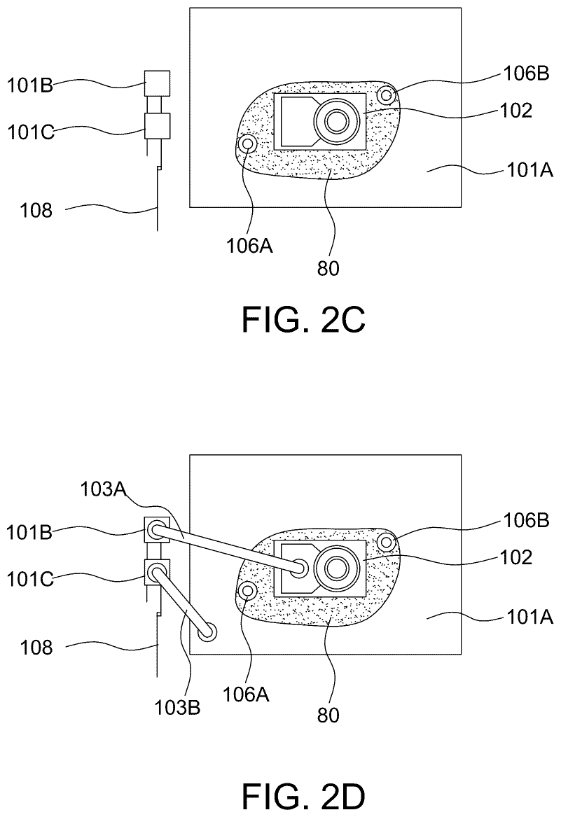

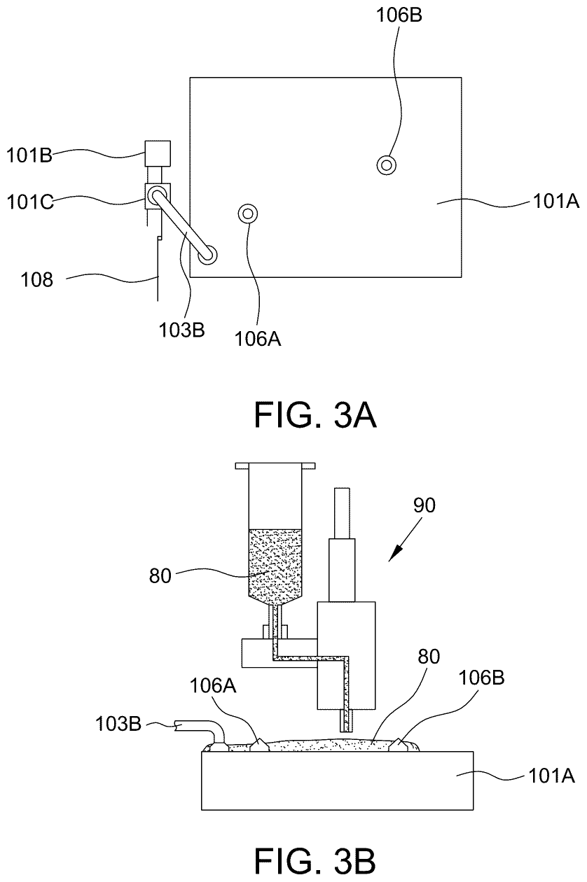

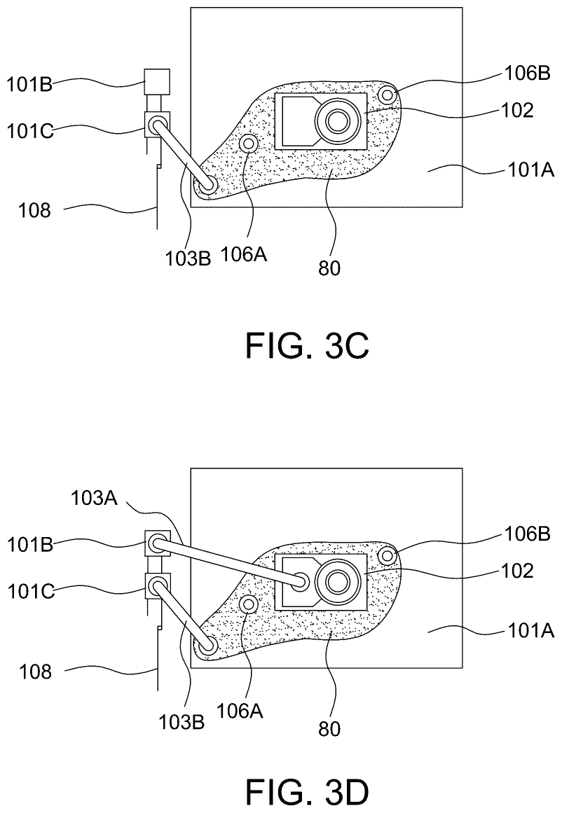

The conductive epoxy 80 is formed on the silicon bond pad 101A using non-contact dispensing technique to fix the light source die 102 on the silicon bond pad 101A and electrically connect thereto. The non-contact dispensing technique is, for example, a jetting dispense using a dispenser 90 shown in FIGS. 2B and 3B, but not limited thereto. Because the silicon bond pad 101A is more fragile than conventional PCBs and leadframes, by forming the conductive epoxy 80 using non-contacting dispensing, the present disclosure is able to avoid directly touching and damaging the surface of the silicon bond pad 101A in dispensing the conductive epoxy 80. Furthermore, because the amount of fillet during the non-contacting dispensing is easier to be controlled accurately, the desired epoxy region and thickness can be formed on the surface of the silicon bond pad 101A to fully cover four corners of the light source die 102 such that shear strength of the light source die 102 attaching to the silicon bond pad 101A is improved.

In addition, because conductivity of the surface of the silicon bond pad 101A may be reduced due to oxidation, the present disclosure further forms at least one stud bump on the surface of the silicon bond pad 101A and within coverage of the conductive epoxy 80 to electrically contact the conductive epoxy 80 before the conductive epoxy 80 is dispensed on the surface of the silicon bond pad 101A. Because an oxidation layer on the silicon bond pad 101A can be broken through (e.g., by ultrasonic power) when the stud bump is disposed by a wire bonder, the electrical connection between the light source die 102 and the silicon bond pad 101A is improved by forming the stud bump.

It should be mentioned that although FIGS. 2A-2D and FIGS. 3A-3D show two stud bumps 106A and 106B beside the light source die 102, they are only intended to illustrate but not to limit the present disclosure. The number of the at least one stud bumps is not limited to two. The material of the at least one stud bump is, for example, gold, cooper, aluminum or a combination thereof.

Furthermore, a top surface of the light sensor IC 100 further includes a first bond pad 101B and a second bond pad 101C. The first bond pad 101B and the second bond pad 101C are, for example, silicon bond pads and are not directly connected to the silicon bond pad 101A as shown in FIGS. 2A and 3A. The first bond pad 101B and the second bond pad 101C are electrically coupled to other components of the light sensor IC 100 via routing 108, e.g., coupled to a processor of the light sensor IC 100. The processor (not shown) is used to, for example, control the light source die 102 to emit light and to process detected signals of the first photodiode 104 and the second photodiode 105. The processor is, for example, an application specific integrated circuit (ASIC), a field programmable gate array (FPGA), a micro controller unit (MCU) or a digital signal processor (DSP), but not limited to.

The light sensor IC 100 further includes a first bonding wire 103A connected between the first bond pad 101B on the surface of the light sensor IC 100 and the light source die 102. The light sensor IC 100 further includes a second bonding wire 103B connected between the second bond pad 101C on the surface of the light sensor IC 100 and the silicon bond pad 101A. The first bonding wire 103A and the second bonding wire 103B are formed by a wire bonder. The method of forming bonding wires is known to the art and thus details thereof are not described herein.

In one aspect, the amount of fillet jetting from a dispenser is controlled to cause coverage of the conductive epoxy 80 to be within a predetermined area and having a predetermined height. For example referring to FIG. 2D, a bond between the second bonding wire 103B and the silicon bond pad 101A is outside the coverage of the conductive epoxy 80 on the silicon bond pad 101A.

In another aspect, to improve the electrical connection between the light source die 102 and the second bonding wire 103B (e.g., in the aspect without arranging the stud bump), a bond between the second bonding wire 103B and the silicon bond pad 101A is inside the coverage of the conductive epoxy 80 on the silicon bond pad 101A, e.g., referring to FIG. 3D.

Referring to FIGS. 2A-2D, they are schematic diagrams of each step of a manufacturing method of a light sensor IC 100 (e.g., shown in FIG. 1) according to a first embodiment of the present disclosure. FIGS. 2A-2D only some components directly related to the present disclosure and omit some components.

Firstly, at least one stud bump (e.g., shown as 106A and 106B, but not limited to two) is formed (e.g., using a wire bonder) on the silicon bond pad 101A within a region predetermined for dispensing conductive epoxy 80, e.g., referring to FIG. 2A.

Then, the conductive epoxy 80 is dispensed on the silicon bond pad 101A using non-contact dispensing. For example, FIG. 2B shows a dispenser 90 used to dispense the conductive epoxy 80. The conductive epoxy 80 covers the stud bumps 106A and 106B so as to electrically contact thereto. As mentioned above, the at least one stud bump is used to break through an oxidation layer on a surface of the silicon bond pad 101A.

Next, the light source die 102 is arranged (e.g., using pick and place device) in the region of conductive epoxy 80, e.g., referring FIG. 2C. By controlling the amount of fillet in non-contact dispensing, the conductive epoxy 80 may fully cover four corners of the light source die 102.

Referring to FIG. 2D, finally a first bonding wire 103A is formed (e.g., using a wire bonder) to connect a first bond pad 101B on the surface of the light sensor IC 100 to a bond pad on the light source die 102, and a second bonding wire 103B is formed (e.g., using the wire bonder) to connect a second bond pad 101C on the surface of the light sensor IC 100 to the silicon bond pad 101A. A sequence of forming the first bonding wire 103A and the second bonding wire 103B is not particularly limited. Now, the process of attaching the light source die 102 directly on the light sensor IC 100 is accomplished.

In the first embodiment, a bond between the second bonding wire 103B and the silicon bond pad 101A is outside coverage of the conductive epoxy 80 on the silicon bond pad 101A. Furthermore, the stud bump is not necessary to be formed in the first embodiment if the oxidation layer on the surface of the silicon bond pad 101A is not a consideration.

Referring to FIGS. 3A-3D, they are schematic diagrams of each step of a manufacturing method of a light sensor IC 100 (e.g., shown in FIG. 1) according to a second embodiment of the present disclosure. FIGS. 3A-3D only some components directly related to the present disclosure and omit some components.

Firstly, at least one stud bump (e.g., shown as 106A and 106B, but not limited to two) is formed (e.g., using a wire bonder) on the silicon bond pad 101A within a region predetermined for dispensing conductive epoxy 80, e.g., referring to FIG. 3A. In addition, before or after forming the stud bump, a second bonding wire 103B is formed (e.g., using the wire bonder) to connect a second bond pad 101C on the surface of the light sensor IC 100 and the silicon bond pad 101A.

Then, the conductive epoxy 80 is dispensed on the silicon bond pad 101A using non-contact dispensing to cover a bond between the second bonding wire 103B and the silicon bond pad 101A to improve the electrical connection between the light source die 102 and the second bonding wire 103B. For example, FIG. 3B shows a dispenser 90 used to dispense the conductive epoxy 80. Similarly, the conductive epoxy 80 covers the stud bumps 106A and 106B so as to electrically contact thereto.

Next, the light source die 102 is arranged (e.g., using pick and place device) in the region of conductive epoxy 80, e.g., referring FIG. 3C.

Referring to FIG. 3D, finally a first bonding wire 103A is formed (e.g., using a wire bonder) to connect a first bond pad 101B on the surface of the light sensor IC 100 to a bond pad on the light source die 102. Now, the process of attaching the light source die 102 directly on the light sensor IC 100 is accomplished.

The main difference of the second embodiment from the first embodiment is on the coverage of the conductive epoxy 80 as well as the time for forming the second bonding wire 103B.

It should be mentioned that although the drawings of the present disclosure show that the silicon bond pad 101A has a rectangular shape, the present disclosure is not limited thereto. The silicon bond pad 101A may have other shapes without particular limitations as long as the light source die 102 is contained therein.

It should be mentioned that the light sensor IC 100 is not limited to be coupled to external circuits using wire bonding technique (i.e. via 109) but using other techniques, such as Flip-chip or Tape-Automated Bonding.

In the present disclosure, the dispenser 90 may use commercial products without particular limitations.

As mentioned above, in the conventional optical sensor devices, the LED die and the light sensor IC are respectively arranged on a leadframe or a PCB, and thus a total size of the package structure is large. Meanwhile, because the silicon bond pad is more fragile than the leadframe and the PCB, the conventional stamping process is not suitable for transferring conductive epoxy onto the silicon bond pad. Accordingly, the present disclosure further provides a light sensor IC (e.g., referring to FIG. 1) and a manufacturing method thereof (e.g., referring to FIGS. 2A-2D and 3A-3D) that directly attaching a light source die on a silicon bond pad of a light sensor using non-contacting dispensing to have benefits of reducing a package size, avoiding damaging the silicon bond pad and improving the shear strength.

Although the disclosure has been explained in relation to its preferred embodiment, it is not used to limit the disclosure. It is to be understood that many other possible modifications and variations can be made by those skilled in the art without departing from the spirit and scope of the disclosure as hereinafter claimed.

1. A light sensor integrated circuit (IC), comprising:
a silicon bond pad, on a surface of the light sensor IC;
a light source die; and
a conductive epoxy, configured to fix the light source die on the silicon bond pad and electrically connect thereto.

2. The light sensor IC as claimed in claim 1, wherein the light sensor IC further comprises a first photodiode and a second photodiode on the surface thereof.

3. The light sensor IC as claimed in claim 2, wherein the silicon bond pad is located between the first photodiode and the second photodiode on the surface of the light sensor IC.

4. The light sensor IC as claimed in claim 1, further comprising at least one stud bump formed on the surface of the light sensor IC and electrically contacted with the conductive epoxy.

5. The light sensor IC as claimed in claim 4, wherein a material of the at least one stud bump is gold, cooper, aluminum or a combination thereof.

6. The light sensor IC as claimed in claim 1, further comprising:
a first bonding wire, connecting a first bond pad on the surface of the light sensor IC with the light source die; and
a second bonding wire, connecting a second bond pad on the surface of the light sensor IC with the silicon bond pad.

7. The light sensor IC as claimed in claim 6, wherein a bond between the second bonding wire and the silicon bond pad is outside coverage of the conductive epoxy on the silicon bond pad.

8. The light sensor IC as claimed in claim 6, wherein a bond between the second bonding wire and the silicon bond pad is inside coverage of the conductive epoxy on the silicon bond pad.

9. A manufacturing method of a light sensor IC, the light sensor IC comprising a silicon bond pad on a surface thereof, the manufacturing method comprising:
dispensing a conductive epoxy region on the silicon bond pad using non-contact dispensing;
attaching a light source die to the conductive epoxy region;
forming a first bonding wire to connect a first bond pad on the surface of the light sensor IC with the light source die; and
forming a second bonding wire to connect a second bond pad on the surface of the light sensor IC with the silicon bond pad.

10. The manufacturing method as claimed in claim 9, wherein before dispensing the conductive epoxy region, the manufacturing method further comprises:
forming at least one stud bump on the silicon bond pad and inside the conductive epoxy region.

11. The manufacturing method as claimed in claim 10, wherein a material of the at least one stud bump is gold, cooper, aluminum or a combination thereof.

12. The manufacturing method as claimed in claim 9, wherein the light sensor IC further comprises a first photodiode and a second photodiode on the surface thereof.

13. The manufacturing method as claimed in claim 12, wherein the silicon bond pad is located between the first photodiode and the second photodiode on the surface of the light sensor IC.

14. The manufacturing method as claimed in claim 9, wherein a bond between the second bonding wire and the silicon bond pad is outside the conductive epoxy region on the silicon bond pad.

15. A manufacturing method of a light sensor IC, the light sensor IC comprising a silicon bond pad on a surface thereof, the manufacturing method comprising:
forming a second bonding wire to connect a second bond pad on the surface of the light sensor IC with the silicon bond pad;
dispensing a conductive epoxy region on the silicon bond pad using non-contact dispensing to cover a bond between the second bonding wire and the silicon bond pad;
attaching a light source die to the conductive epoxy region; and
forming a first bonding wire to connect a first bond pad on the surface of the light sensor IC with the light source die.

16. The manufacturing method as claimed in claim 15, wherein before dispensing the conductive epoxy region, the manufacturing method further comprises:
forming at least one stud bump on the silicon bond pad and inside the conductive epoxy region.

17. The manufacturing method as claimed in claim 16, wherein a material of the at least one stud bump is gold, cooper, aluminum or a combination thereof.

18. The manufacturing method as claimed in claim 15, wherein the light sensor IC further comprises a first photodiode and a second photodiode on the surface thereof.

19. The manufacturing method as claimed in claim 18, wherein the silicon bond pad is located between the first photodiode and the second photodiode on the surface of the light sensor IC.
